(19) United States
(12) Patent Application Publication
(10) Pub. No.: US 2023/0147392 A1
(43) Pub. Date: May 11, 2023

(54) TWO-AXIS TEST FIXTURE

(71) Applicant: MOTIONAL AD LLC, Boston, MA (US)

(72) Inventor: Joseph Brassard, Cambridge, MA (US)

(21) Appl. No.: 17/523,220

(22) Filed: Nov. 10, 2021

(51) Int. Cl. G01R 1/04; H02K 13/00; G01R 35/00

(52) U.S. Cl. CPC G01R 1/0491; H02K 13/003; G01R 35/005; G01R 1/0416

(57) ABSTRACT

Provided is a two axis test fixture, which can include systems and associated methods. Some methods described also include implementing and/or controlling a two-axis test fixture. Systems and computer program products are also provided. A test fixture is used to test, calibrate, or validate an IMU. The test fixture is operable to rotate a device under test (e.g., IMU) along two axes while mounted to a turntable. The rotation of the turntable is enabled via multiple slip rings, rotational bearings, and standoff fixtures. Testing of the device along greater than two axes is achieved through rotation of the device under test on the turntable, and revolutions of the device under test about an axle.

### BACKGROUND

Inertial devices, such as an inertial measurement unit (IMU), capture raw data that is used to determine inertial information such as orientation, velocity, and acceleration. An IMU includes a combination or one or more accelerometers, gyroscopes, and magnetometers that capture data associated with movement imparted on the IMU. Inertial information can be used to maneuver an autonomous vehicle, and inertial devices are tested to verify proper operation of the inertial device.

### BRIEF DESCRIPTION OF THE FIGURES

FIG. 1 is an example environment in which a vehicle including one or more components of an autonomous system can be implemented;

FIG. 2 is a diagram of one or more systems of a vehicle including an autonomous system;

FIG. 3 is a diagram of components of one or more devices and/or one or more systems of FIGS. 1 and 2;

FIG. 4 is a diagram of certain components of an autonomous system;

FIG. 5 is a block diagram of a two-axis test fixture;

FIG. 6 is an illustration of a test system; and

FIG. 7 is a process flow diagram of a process for control of a two-axis test fixture.

### DETAILED DESCRIPTION

In the following description numerous specific details are set forth in order to provide a thorough understanding of the present disclosure for the purposes of explanation. It will be apparent, however, that the embodiments described by the present disclosure can be practiced without these specific details. In some instances, well-known structures and devices are illustrated in block diagram form in order to avoid unnecessarily obscuring aspects of the present disclosure.

Specific arrangements or orderings of schematic elements, such as those representing systems, devices, modules, instruction blocks, data elements, and/or the like are illustrated in the drawings for ease of description. However, it will be understood by those skilled in the art that the specific ordering or arrangement of the schematic elements in the drawings is not meant to imply that a particular order or sequence of processing, or separation of processes, is required unless explicitly described as such. Further, the inclusion of a schematic element in a drawing is not meant to imply that such element is required in all embodiments or that the features represented by such element may not be included in or combined with other elements in some embodiments unless explicitly described as such.

Further, where connecting elements such as solid or dashed lines or arrows are used in the drawings to illustrate a connection, relationship, or association between or among two or more other schematic elements, the absence of any such connecting elements is not meant to imply that no connection, relationship, or association can exist. In other words, some connections, relationships, or associations between elements are not illustrated in the drawings so as not to obscure the disclosure. In addition, for ease of illustration, a single connecting element can be used to represent multiple connections, relationships or associations between elements. For example, where a connecting element represents communication of signals, data, or instructions (e.g., “software instructions”), it should be understood by those skilled in the art that such element can represent one or multiple signal paths (e.g., a bus), as may be needed, to affect the communication.

Although the terms first, second, third, and/or the like are used to describe various elements, these elements should not be limited by these terms. The terms first, second, third, and/or the like are used only to distinguish one element from another. For example, a first contact could be termed a second contact and, similarly, a second contact could be termed a first contact without departing from the scope of the described embodiments. The first contact and the second contact are both contacts, but they are not the same contact.

The terminology used in the description of the various described embodiments herein is included for the purpose of describing particular embodiments only and is not intended to be limiting. As used in the description of the various described embodiments and the appended claims, the singular forms “a,” “an” and “the” are intended to include the plural forms as well and can be used interchangeably with “one or more” or “at least one,” unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this description specify the presence of stated features, integers, steps, operations, elements, and/or components, but do not preclude the presence or addition of one or more other features, integers, steps, operations, elements, components, and/or groups thereof.

As used herein, the terms “communication” and “communicate” refer to at least one of the reception, receipt, transmission, transfer, provision, and/or the like of information (or information represented by, for example, data, signals, messages, instructions, commands, and/or the like). For one unit (e.g., a device, a system, a component of a device or system, combinations thereof, and/or the like) to be in communication with another unit means that the one unit is able to directly or indirectly receive information from and/or send (e.g., transmit) information to the other unit. This may refer to a direct or indirect connection that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit (e.g., a third unit located between the first unit and the second unit) processes information received from the first unit and transmits the processed information to the second unit. In some embodiments, a message may refer to a network packet (e.g., a data packet and/or the like) that includes data.

As used herein, the term “if” is, optionally, construed to mean “when”, “upon”, “in response to determining,” “in response to detecting,” and/or the like, depending on the context. Similarly, the phrase “if it is determined” or “if [a stated condition or event] is detected” is, optionally, construed to mean “upon determining,” “in response to determining,” “upon detecting [the stated condition or event],” “in response to detecting [the stated condition or event],” and/or the like, depending on the context. Also, as used herein, the terms “has”, “have”, “having”, or the like are intended to be open-ended terms. Further, the phrase “based on” is intended to mean “based at least partially on” unless explicitly stated otherwise.

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments can be practiced without these specific details. In other instances, well-known methods, procedures, components, circuits, and networks have not been described in detail so as not to unnecessarily obscure aspects of the embodiments.

General Overview

In some aspects and/or embodiments, systems, methods, and computer program products described herein include, implement, and/or control a two-axis test fixture. A vehicle (such as an autonomous vehicle) can have any number of sensors and devices that enable varying levels of autonomous functionality. In some cases, an autonomous vehicle (AV) includes at least one inertial measurement unit (IMU). Generally, an IMU is a device that captures data associated with movement imparted on the IMU. When the IMU is located in or on an AV, the IMU captures data related to the movement of the AV. IMUs are available in varying sizes. A test fixture is used to test, calibrate, or validate an IMU. The test fixture is operable to rotate a device under test (e.g., IMU) along two axes while mounted to a turntable. The rotation of the turntable is enabled via multiple slip rings, rotational bearings, and standoff fixtures. Testing of the device along greater than two axes is achieved through rotation of the device under test on the turntable, and revolutions of the device under test about an axle.

By virtue of the implementation of systems, methods, and computer program products described herein, techniques for a two-axis test fixture enables efficient testing of an inertial device. In particular, advantages of these techniques include a testing of a relatively small device under test with a low-cost fixture. The present techniques also enable isolation of the device under test inside a temperature chamber, vacuum, or any combinations thereof.

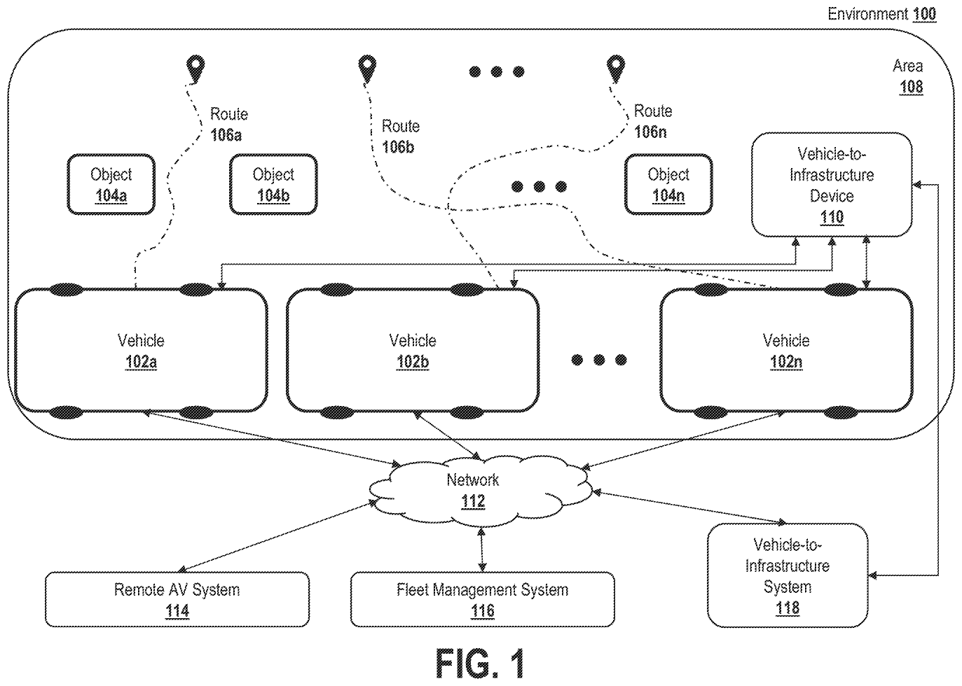

Referring now to FIG. 1, illustrated is example environment 100 in which vehicles that include autonomous systems, as well as vehicles that do not, are operated. As illustrated, environment 100 includes vehicles 102a-102n, objects 104a-104n, routes 106a-106n, area 108, vehicle-to-infrastructure (V2I) device 110, network 112, remote autonomous vehicle (AV) system 114, fleet management system 116, and V2I system 118. Vehicles 102a-102n, vehicle-to-infrastructure (V2I) device 110, network 112, autonomous vehicle (AV) system 114, fleet management system 116, and V2I system 118 interconnect (e.g., establish a connection to communicate and/or the like) via wired connections, wireless connections, or a combination of wired or wireless connections. In some embodiments, objects 104a-104n interconnect with at least one of vehicles 102a-102n, vehicle-to-infrastructure (V2I) device 110, network 112, autonomous vehicle (AV) system 114, fleet management system 116, and V2I system 118 via wired connections, wireless connections, or a combination of wired or wireless connections.

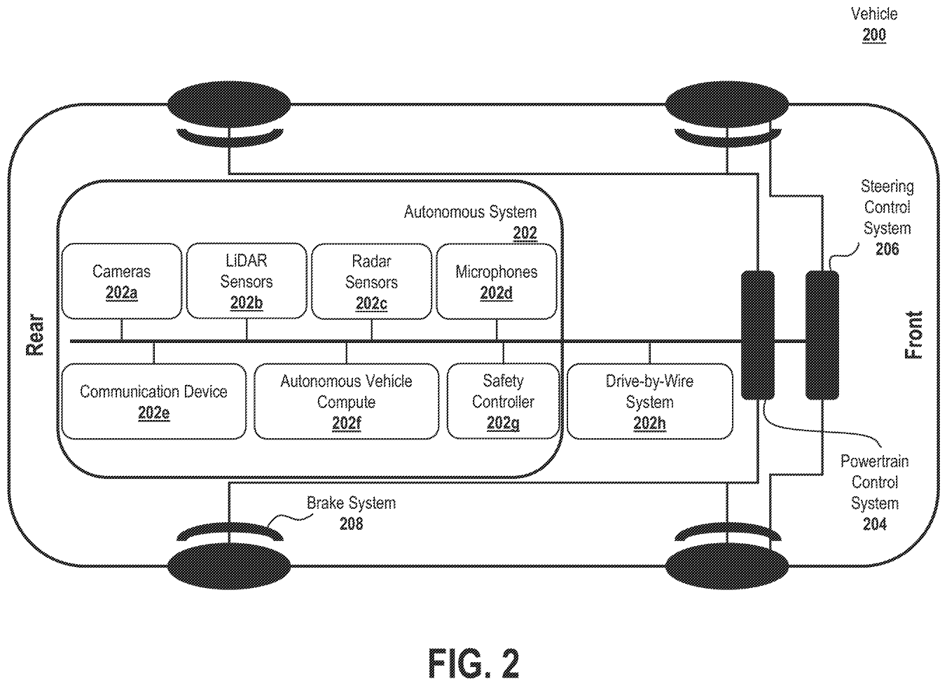

Vehicles 102a-102n (referred to individually as vehicle 102 and collectively as vehicles 102) include at least one device configured to transport goods and/or people. In some embodiments, vehicles 102 are configured to be in communication with V2I device 110, remote AV system 114, fleet management system 116, and/or V2I system 118 via network 112. In some embodiments, vehicles 102 include cars, buses, trucks, trains, and/or the like. In some embodiments, vehicles 102 are the same as, or similar to, vehicles 200, described herein (see FIG. 2). In some embodiments, a vehicle 200 of a set of vehicles 200 is associated with an autonomous fleet manager. In some embodiments, vehicles 102 travel along respective routes 106a-106n (referred to individually as route 106 and collectively as routes 106), as described herein. In some embodiments, one or more vehicles 102 include an autonomous system (e.g., an autonomous system that is the same as or similar to autonomous system 202).

Objects 104a-104n (referred to individually as object 104 and collectively as objects 104) include, for example, at least one vehicle, at least one pedestrian, at least one cyclist, at least one structure (e.g., a building, a sign, a fire hydrant, etc.), and/or the like. Each object 104 is stationary (e.g., located at a fixed location for a period of time) or mobile (e.g., having a velocity and associated with at least one trajectory). In some embodiments, objects 104 are associated with corresponding locations in area 108.

Routes 106a-106n (referred to individually as route 106 and collectively as routes 106) are each associated with (e.g., prescribe) a sequence of actions (also known as a trajectory) connecting states along which an AV can navigate. Each route 106 starts at an initial state (e.g., a state that corresponds to a first spatiotemporal location, velocity, and/or the like) and a final goal state (e.g., a state that corresponds to a second spatiotemporal location that is different from the first spatiotemporal location) or goal region (e.g. a subspace of acceptable states (e.g., terminal states)). In some embodiments, the first state includes a location at which an individual or individuals are to be picked-up by the AV and the second state or region includes a location or locations at which the individual or individuals picked-up by the AV are to be dropped-off. In some embodiments, routes 106 include a plurality of acceptable state sequences (e.g., a plurality of spatiotemporal location sequences), the plurality of state sequences associated with (e.g., defining) a plurality of trajectories. In an example, routes 106 include only high level actions or imprecise state locations, such as a series of connected roads dictating turning directions at roadway intersections. Additionally, or alternatively, routes 106 may include more precise actions or states such as, for example, specific target lanes or precise locations within the lane areas and targeted speed at those positions. In an example, routes 106 include a plurality of precise state sequences along the at least one high level action sequence with a limited lookahead horizon to reach intermediate goals, where the combination of successive iterations of limited horizon state sequences cumulatively correspond to a plurality of trajectories that collectively form the high level route to terminate at the final goal state or region.

Area 108 includes a physical area (e.g., a geographic region) within which vehicles 102 can navigate. In an example, area 108 includes at least one state (e.g., a country, a province, an individual state of a plurality of states included in a country, etc.), at least one portion of a state, at least one city, at least one portion of a city, etc. In some embodiments, area 108 includes at least one named thoroughfare (referred to herein as a “road”) such as a highway, an interstate highway, a parkway, a city street, etc. Additionally, or alternatively, in some examples area 108 includes at least one unnamed road such as a driveway, a section of a parking lot, a section of a vacant and/or undeveloped lot, a dirt path, etc. In some embodiments, a road includes at least one lane (e.g., a portion of the road that can be traversed by vehicles 102). In an example, a road includes at least one lane associated with (e.g., identified based on) at least one lane marking.

Vehicle-to-Infrastructure (V2I) device 110 (sometimes referred to as a Vehicle-to-Infrastructure (V2X) device) includes at least one device configured to be in communication with vehicles 102 and/or V2I infrastructure system 118. In some embodiments, V2I device 110 is configured to be in communication with vehicles 102, remote AV system 114, fleet management system 116, and/or V2I system 118 via network 112. In some embodiments, V2I device 110 includes a radio frequency identification (RFID) device, signage, cameras (e.g., two-dimensional (2D) and/or three-dimensional (3D) cameras), lane markers, streetlights, parking meters, etc. In some embodiments, V2I device 110 is configured to communicate directly with vehicles 102. Additionally, or alternatively, in some embodiments V2I device 110 is configured to communicate with vehicles 102, remote AV system 114, and/or fleet management system 116 via V2I system 118. In some embodiments, V2I device 110 is configured to communicate with V2I system 118 via network 112.

Network 112 includes one or more wired and/or wireless networks. In an example, network 112 includes a cellular network (e.g., a long term evolution (LTE) network, a third generation (3G) network, a fourth generation (4G) network, a fifth generation (5G) network, a code division multiple access (CDMA) network, etc.), a public land mobile network (PLMN), a local area network (LAN), a wide area network (WAN), a metropolitan area network (MAN), a telephone network (e.g., the public switched telephone network (PSTN), a private network, an ad hoc network, an intranet, the Internet, a fiber optic-based network, a cloud computing network, etc., a combination of some or all of these networks, and/or the like.

Remote AV system 114 includes at least one device configured to be in communication with vehicles 102, V2I device 110, network 112, remote AV system 114, fleet management system 116, and/or V2I system 118 via network 112. In an example, remote AV system 114 includes a server, a group of servers, and/or other like devices. In some embodiments, remote AV system 114 is co-located with the fleet management system 116. In some embodiments, remote AV system 114 is involved in the installation of some or all of the components of a vehicle, including an autonomous system, an autonomous vehicle compute, software implemented by an autonomous vehicle compute, and/or the like. In some embodiments, remote AV system 114 maintains (e.g., updates and/or replaces) such components and/or software during the lifetime of the vehicle.

Fleet management system 116 includes at least one device configured to be in communication with vehicles 102, V2I device 110, remote AV system 114, and/or V2I infrastructure system 118. In an example, fleet management system 116 includes a server, a group of servers, and/or other like devices. In some embodiments, fleet management system 116 is associated with a ridesharing company (e.g., an organization that controls operation of multiple vehicles (e.g., vehicles that include autonomous systems and/or vehicles that do not include autonomous systems) and/or the like).

In some embodiments, V2I system 118 includes at least one device configured to be in communication with vehicles 102, V2I device 110, remote AV system 114, and/or fleet management system 116 via network 112. In some examples, V2I system 118 is configured to be in communication with V2I device 110 via a connection different from network 112. In some embodiments, V2I system 118 includes a server, a group of servers, and/or other like devices. In some embodiments, V2I system 118 is associated with a municipality or a private institution (e.g., a private institution that maintains V2I device 110 and/or the like).

The number and arrangement of elements illustrated in FIG. 1 are provided as an example. There can be additional elements, fewer elements, different elements, and/or differently arranged elements, than those illustrated in FIG. 1. Additionally, or alternatively, at least one element of environment 100 can perform one or more functions described as being performed by at least one different element of FIG. 1. Additionally, or alternatively, at least one set of elements of environment 100 can perform one or more functions described as being performed by at least one different set of elements of environment 100.

Referring now to FIG. 2, vehicle 200 includes autonomous system 202, powertrain control system 204, steering control system 206, and brake system 208. In some embodiments, vehicle 200 is the same as or similar to vehicle 102 (see FIG. 1). In some embodiments, vehicle 102 have autonomous capability (e.g., implement at least one function, feature, device, and/or the like that enable vehicle 200 to be partially or fully operated without human intervention including, without limitation, fully autonomous vehicles (e.g., vehicles that forego reliance on human intervention), highly autonomous vehicles (e.g., vehicles that forego reliance on human intervention in certain situations), and/or the like). For a detailed description of fully autonomous vehicles and highly autonomous vehicles, reference may be made to SAE International's standard J3016: Taxonomy and Definitions for Terms Related to On-Road Motor Vehicle Automated Driving Systems, which is incorporated by reference in its entirety. In some embodiments, vehicle 200 is associated with an autonomous fleet manager and/or a ridesharing company.

Autonomous system 202 includes a sensor suite that includes one or more devices such as cameras 202a, LiDAR sensors 202b, radar sensors 202c, and microphones 202d. In some embodiments, autonomous system 202 can include more or fewer devices and/or different devices (e.g., ultrasonic sensors, inertial sensors, GPS receivers (discussed below), odometry sensors that generate data associated with an indication of a distance that vehicle 200 has traveled, and/or the like). In some embodiments, autonomous system 202 uses the one or more devices included in autonomous system 202 to generate data associated with environment 100, described herein. The data generated by the one or more devices of autonomous system 202 can be used by one or more systems described herein to observe the environment (e.g., environment 100) in which vehicle 200 is located. In some embodiments, autonomous system 202 includes communication device 202e, autonomous vehicle compute 202f, and drive-by-wire (DBW) system 202h.

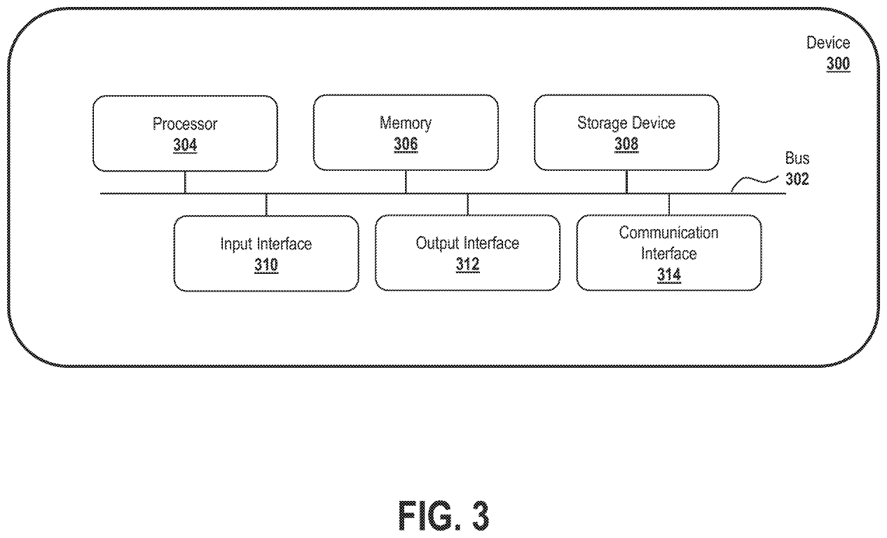

Cameras 202a include at least one device configured to be in communication with communication device 202e, autonomous vehicle compute 202f, and/or safety controller 202g via a bus (e.g., a bus that is the same as or similar to bus 302 of FIG. 3). Cameras 202a include at least one camera (e.g., a digital camera using a light sensor such as a charge-coupled device (CCD), a thermal camera, an infrared (IR) camera, an event camera, and/or the like) to capture images including physical objects (e.g., cars, buses, curbs, people, and/or the like). In some embodiments, camera 202a generates camera data as output. In some examples, camera 202a generates camera data that includes image data associated with an image. In this example, the image data may specify at least one parameter (e.g., image characteristics such as exposure, brightness, etc., an image timestamp, and/or the like) corresponding to the image. In such an example, the image may be in a format (e.g., RAW, JPEG, PNG, and/or the like). In some embodiments, camera 202a includes a plurality of independent cameras configured on (e.g., positioned on) a vehicle to capture images for the purpose of stereopsis (stereo vision). In some examples, camera 202a includes a plurality of cameras that generate image data and transmit the image data to autonomous vehicle compute 202f and/or a fleet management system (e.g., a fleet management system that is the same as or similar to fleet management system 116 of FIG. 1). In such an example, autonomous vehicle compute 202f determines depth to one or more objects in a field of view of at least two cameras of the plurality of cameras based on the image data from the at least two cameras. In some embodiments, cameras 202a is configured to capture images of objects within a distance from cameras 202a (e.g., up to 100 meters, up to a kilometer, and/or the like). Accordingly, cameras 202a include features such as sensors and lenses that are optimized for perceiving objects that are at one or more distances from cameras 202a.

In an embodiment, camera 202a includes at least one camera configured to capture one or more images associated with one or more traffic lights, street signs and/or other physical objects that provide visual navigation information. In some embodiments, camera 202a generates traffic light data associated with one or more images. In some examples, camera 202a generates TLD data associated with one or more images that include a format (e.g., RAW, JPEG, PNG, and/or the like). In some embodiments, camera 202a that generates TLD data differs from other systems described herein incorporating cameras in that camera 202a can include one or more cameras with a wide field of view (e.g., a wide-angle lens, a fish-eye lens, a lens having a viewing angle of approximately 120 degrees or more, and/or the like) to generate images about as many physical objects as possible.

Laser Detection and Ranging (LiDAR) sensors 202b include at least one device configured to be in communication with communication device 202e, autonomous vehicle compute 202f, and/or safety controller 202g via a bus (e.g., a bus that is the same as or similar to bus 302 of FIG. 3). LiDAR sensors 202b include a system configured to transmit light from a light emitter (e.g., a laser transmitter). Light emitted by LiDAR sensors 202b include light (e.g., infrared light and/or the like) that is outside of the visible spectrum. In some embodiments, during operation, light emitted by LiDAR sensors 202b encounters a physical object (e.g., a vehicle) and is reflected back to LiDAR sensors 202b. In some embodiments, the light emitted by LiDAR sensors 202b does not penetrate the physical objects that the light encounters. LiDAR sensors 202b also include at least one light detector which detects the light that was emitted from the light emitter after the light encounters a physical object. In some embodiments, at least one data processing system associated with LiDAR sensors 202b generates an image (e.g., a point cloud, a combined point cloud, and/or the like) representing the objects included in a field of view of LiDAR sensors 202b. In some examples, the at least one data processing system associated with LiDAR sensor 202b generates an image that represents the boundaries of a physical object, the surfaces (e.g., the topology of the surfaces) of the physical object, and/or the like. In such an example, the image is used to determine the boundaries of physical objects in the field of view of LiDAR sensors 202b.

Radio Detection and Ranging (radar) sensors 202c include at least one device configured to be in communication with communication device 202e, autonomous vehicle compute 202f, and/or safety controller 202g via a bus (e.g., a bus that is the same as or similar to bus 302 of FIG. 3). Radar sensors 202c include a system configured to transmit radio waves (either pulsed or continuously). The radio waves transmitted by radar sensors 202c include radio waves that are within a predetermined spectrum. In some embodiments, during operation, radio waves transmitted by radar sensors 202c encounter a physical object and are reflected back to radar sensors 202c. In some embodiments, the radio waves transmitted by radar sensors 202c are not reflected by some objects. In some embodiments, at least one data processing system associated with radar sensors 202c generates signals representing the objects included in a field of view of radar sensors 202c. For example, the at least one data processing system associated with radar sensor 202c generates an image that represents the boundaries of a physical object, the surfaces (e.g., the topology of the surfaces) of the physical object, and/or the like. In some examples, the image is used to determine the boundaries of physical objects in the field of view of radar sensors 202c.

Microphones 202d includes at least one device configured to be in communication with communication device 202e, autonomous vehicle compute 202f, and/or safety controller 202g via a bus (e.g., a bus that is the same as or similar to bus 302 of FIG. 3). Microphones 202d include one or more microphones (e.g., array microphones, external microphones, and/or the like) that capture audio signals and generate data associated with (e.g., representing) the audio signals. In some examples, microphones 202d include transducer devices and/or like devices. In some embodiments, one or more systems described herein can receive the data generated by microphones 202d and determine a position of an object relative to vehicle 200 (e.g., a distance and/or the like) based on the audio signals associated with the data.

Communication device 202e include at least one device configured to be in communication with cameras 202a, LiDAR sensors 202b, radar sensors 202c, microphones 202d, autonomous vehicle compute 202f, safety controller 202g, and/or DBW system 202h. For example, communication device 202e may include a device that is the same as or similar to communication interface 314 of FIG. 3. In some embodiments, communication device 202e includes a vehicle-to-vehicle (V2V) communication device (e.g., a device that enables wireless communication of data between vehicles).

Autonomous vehicle compute 202f includes at least one device configured to be in communication with cameras 202a, LiDAR sensors 202b, radar sensors 202c, microphones 202d, communication device 202e, safety controller 202g, and/or DBW system 202h. In some examples, autonomous vehicle compute 202f includes a device such as a client device, a mobile device (e.g., a cellular telephone, a tablet, and/or the like) a server (e.g., a computing device including one or more central processing units, graphical processing units, and/or the like), and/or the like. In some embodiments, autonomous vehicle compute 202f is the same as or similar to autonomous vehicle compute 400, described herein. Additionally, or alternatively, in some embodiments autonomous vehicle compute 202f is configured to be in communication with an autonomous vehicle system (e.g., an autonomous vehicle system that is the same as or similar to remote AV system 114 of FIG. 1), a fleet management system (e.g., a fleet management system that is the same as or similar to fleet management system 116 of FIG. 1), a V2I device (e.g., a V2I device that is the same as or similar to V2I device 110 of FIG. 1), and/or a V2I system (e.g., a V2I system that is the same as or similar to V2I system 118 of FIG. 1).

Safety controller 202g includes at least one device configured to be in communication with cameras 202a, LiDAR sensors 202b, radar sensors 202c, microphones 202d, communication device 202e, autonomous vehicle computer 202f, and/or DBW system 202h. In some examples, safety controller 202g includes one or more controllers (electrical controllers, electromechanical controllers, and/or the like) that are configured to generate and/or transmit control signals to operate one or more devices of vehicle 200 (e.g., powertrain control system 204, steering control system 206, brake system 208, and/or the like). In some embodiments, safety controller 202g is configured to generate control signals that take precedence over (e.g., overrides) control signals generated and/or transmitted by autonomous vehicle compute 202f.

DBW system 202h includes at least one device configured to be in communication with communication device 202e and/or autonomous vehicle compute 202f. In some examples, DBW system 202h includes one or more controllers (e.g., electrical controllers, electromechanical controllers, and/or the like) that are configured to generate and/or transmit control signals to operate one or more devices of vehicle 200 (e.g., powertrain control system 204, steering control system 206, brake system 208, and/or the like). Additionally, or alternatively, the one or more controllers of DBW system 202h are configured to generate and/or transmit control signals to operate at least one different device (e.g., a turn signal, headlights, door locks, windshield wipers, and/or the like) of vehicle 200.

Powertrain control system 204 includes at least one device configured to be in communication with DBW system 202h. In some examples, powertrain control system 204 includes at least one controller, actuator, and/or the like. In some embodiments, powertrain control system 204 receives control signals from DBW system 202h and powertrain control system 204 causes vehicle 200 to start moving forward, stop moving forward, start moving backward, stop moving backward, accelerate in a direction, decelerate in a direction, perform a left turn, perform a right turn, and/or the like. In an example, powertrain control system 204 causes the energy (e.g., fuel, electricity, and/or the like) provided to a motor of the vehicle to increase, remain the same, or decrease, thereby causing at least one wheel of vehicle 200 to rotate or not rotate.

Steering control system 206 includes at least one device configured to rotate one or more wheels of vehicle 200. In some examples, steering control system 206 includes at least one controller, actuator, and/or the like. In some embodiments, steering control system 206 causes the front two wheels and/or the rear two wheels of vehicle 200 to rotate to the left or right to cause vehicle 200 to turn to the left or right.

Brake system 208 includes at least one device configured to actuate one or more brakes to cause vehicle 200 to reduce speed and/or remain stationary. In some examples, brake system 208 includes at least one controller and/or actuator that is configured to cause one or more calipers associated with one or more wheels of vehicle 200 to close on a corresponding rotor of vehicle 200. Additionally, or alternatively, in some examples brake system 208 includes an automatic emergency braking (AEB) system, a regenerative braking system, and/or the like.

In some embodiments, vehicle 200 includes at least one platform sensor (not explicitly illustrated) that measures or infers properties of a state or a condition of vehicle 200. In some examples, vehicle 200 includes platform sensors such as a global positioning system (GPS) receiver, an inertial measurement unit (IMU), a wheel speed sensor, a wheel brake pressure sensor, a wheel torque sensor, an engine torque sensor, a steering angle sensor, and/or the like.

Referring now to FIG. 3, illustrated is a schematic diagram of a device 300. As illustrated, device 300 includes processor 304, memory 306, storage component 308, input interface 310, output interface 312, communication interface 314, and bus 302. In some embodiments, device 300 corresponds to at least one device of vehicles 102 (e.g., at least one device of a system of vehicles 102), at least one device under test (e.g., IMU), and/or one or more devices of network 112 (e.g., one or more devices of a system of network 112). In some embodiments, one or more devices of vehicles 102 (e.g., one or more devices of a system of vehicles 102), a device under test (e.g., IMU), and/or one or more devices of network 112 (e.g., one or more devices of a system of network 112) include at least one device 300 and/or at least one component of device 300. As shown in FIG. 3, device 300 includes bus 302, processor 304, memory 306, storage component 308, input interface 310, output interface 312, and communication interface 314.

Bus 302 includes a component that permits communication among the components of device 300. In some embodiments, processor 304 is implemented in hardware, software, or a combination of hardware and software. In some examples, processor 304 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 306 includes random access memory (RAM), read-only memory (ROM), and/or another type of dynamic and/or static storage device (e.g., flash memory, magnetic memory, optical memory, and/or the like) that stores data and/or instructions for use by processor 304.

Storage component 308 stores data and/or software related to the operation and use of device 300. In some examples, storage component 308 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 310 includes a component that permits device 300 to receive information, such as via user input (e.g., a touchscreen display, a keyboard, a keypad, a mouse, a button, a switch, a microphone, a camera, and/or the like). Additionally or alternatively, in some embodiments input interface 310 includes a sensor that senses information (e.g., a global positioning system (GPS) receiver, an accelerometer, a gyroscope, an actuator, and/or the like). Output interface 312 includes a component that provides output information from device 300 (e.g., a display, a speaker, one or more light-emitting diodes (LEDs), and/or the like).

In some embodiments, communication interface 314 includes a transceiver-like component (e.g., a transceiver, a separate receiver and transmitter, and/or the like) that permits device 300 to communicate with other devices via a wired connection, a wireless connection, or a combination of wired and wireless connections. In some examples, communication interface 314 permits device 300 to receive information from another device and/or provide information to another device. In some examples, communication interface 314 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, device 300 performs one or more processes described herein. Device 300 performs these processes based on processor 304 executing software instructions stored by a computer-readable medium, such as memory 305 and/or storage component 308. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 306 and/or storage component 308 from another computer-readable medium or from another device via communication interface 314. When executed, software instructions stored in memory 306 and/or storage component 308 cause processor 304 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 306 and/or storage component 308 includes data storage or at least one data structure (e.g., a database and/or the like). Device 300 is capable of receiving information from, storing information in, communicating information to, or searching information stored in the data storage or the at least one data structure in memory 306 or storage component 308. In some examples, the information includes network data, input data, output data, or any combination thereof.

In some embodiments, device 300 is configured to execute software instructions that are either stored in memory 306 and/or in the memory of another device (e.g., another device that is the same as or similar to device 300). As used herein, the term “module” refers to at least one instruction stored in memory 306 and/or in the memory of another device that, when executed by processor 304 and/or by a processor of another device (e.g., another device that is the same as or similar to device 300) cause device 300 (e.g., at least one component of device 300) to perform one or more processes described herein. In some embodiments, a module is implemented in software, firmware, hardware, and/or the like.

The number and arrangement of components illustrated in FIG. 3 are provided as an example. In some embodiments, device 300 can include additional components, fewer components, different components, or differently arranged components than those illustrated in FIG. 3. Additionally or alternatively, a set of components (e.g., one or more components) of device 300 can perform one or more functions described as being performed by another component or another set of components of device 300.

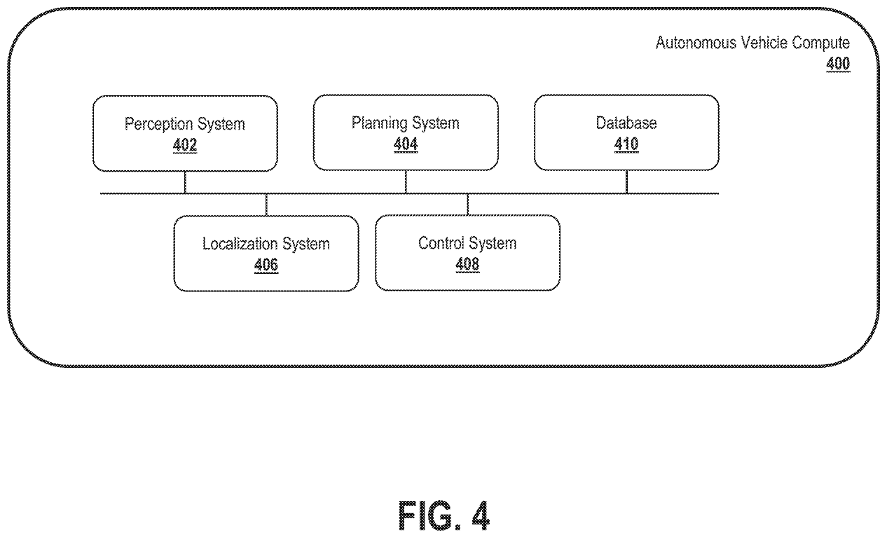

Referring now to FIG. 4, illustrated is an example block diagram of an autonomous vehicle compute 400 (sometimes referred to as an “AV stack”). As illustrated, autonomous vehicle compute 400 includes perception system 402 (sometimes referred to as a perception module), planning system 404 (sometimes referred to as a planning module), localization system 406 (sometimes referred to as a localization module), control system 408 (sometimes referred to as a control module), and database 410. In some embodiments, perception system 402, planning system 404, localization system 406, control system 408, and database 410 are included and/or implemented in an autonomous navigation system of a vehicle (e.g., autonomous vehicle compute 202f of vehicle 200). Additionally, or alternatively, in some embodiments perception system 402, planning system 404, localization system 406, control system 408, and database 410 are included in one or more standalone systems (e.g., one or more systems that are the same as or similar to autonomous vehicle compute 400 and/or the like). In some examples, perception system 402, planning system 404, localization system 406, control system 408, and database 410 are included in one or more standalone systems that are located in a vehicle and/or at least one remote system as described herein. In some embodiments, any and/or all of the systems included in autonomous vehicle compute 400 are implemented in software (e.g., in software instructions stored in memory), computer hardware (e.g., by microprocessors, microcontrollers, application-specific integrated circuits [ASICs], Field Programmable Gate Arrays (FPGAs), and/or the like), or combinations of computer software and computer hardware. It will also be understood that, in some embodiments, autonomous vehicle compute 400 is configured to be in communication with a remote system (e.g., an autonomous vehicle system that is the same as or similar to remote AV system 114, a fleet management system 116 that is the same as or similar to fleet management system 116, a V2I system that is the same as or similar to V2I system 118, and/or the like).

In some embodiments, perception system 402 receives data associated with at least one physical object (e.g., data that is used by perception system 402 to detect the at least one physical object) in an environment and classifies the at least one physical object. In some examples, perception system 402 receives image data captured by at least one camera (e.g., cameras 202a), the image data associated with (e.g., representing) one or more physical objects within a field of view of the at least one camera. In such an example, perception system 402 classifies at least one physical object based on one or more groupings of physical objects (e.g., bicycles, vehicles, traffic signs, pedestrians, and/or the like). In some embodiments, perception system 402 transmits data associated with the classification of the physical objects to planning system 404 based on perception system 402 classifying the physical objects.

In some embodiments, planning system 404 receives data associated with a destination and generates data associated with at least one route (e.g., routes 106) along which a vehicle (e.g., vehicles 102) can travel along toward a destination. In some embodiments, planning system 404 periodically or continuously receives data from perception system 402 (e.g., data associated with the classification of physical objects, described above) and planning system 404 updates the at least one trajectory or generates at least one different trajectory based on the data generated by perception system 402. In some embodiments, planning system 404 receives data associated with an updated position of a vehicle (e.g., vehicles 102) from localization system 406 and planning system 404 updates the at least one trajectory or generates at least one different trajectory based on the data generated by localization system 406.

In some embodiments, localization system 406 receives data associated with (e.g., representing) a location of a vehicle (e.g., vehicles 102) in an area. In some examples, localization system 406 receives LiDAR data associated with at least one point cloud generated by at least one LiDAR sensor (e.g., LiDAR sensors 202b). In certain examples, localization system 406 receives data associated with at least one point cloud from multiple LiDAR sensors and localization system 406 generates a combined point cloud based on each of the point clouds. In these examples, localization system 406 compares the at least one point cloud or the combined point cloud to two-dimensional (2D) and/or a three-dimensional (3D) map of the area stored in database 410. Localization system 406 then determines the position of the vehicle in the area based on localization system 406 comparing the at least one point cloud or the combined point cloud to the map. In some embodiments, the map includes a combined point cloud of the area generated prior to navigation of the vehicle. In some embodiments, maps include, without limitation, high-precision maps of the roadway geometric properties, maps describing road network connectivity properties, maps describing roadway physical properties (such as traffic speed, traffic volume, the number of vehicular and cyclist traffic lanes, lane width, lane traffic directions, or lane marker types and locations, or combinations thereof), and maps describing the spatial locations of road features such as crosswalks, traffic signs or other travel signals of various types. In some embodiments, the map is generated in real-time based on the data received by the perception system.

In another example, localization system 406 receives Global Navigation Satellite System (GNSS) data generated by a global positioning system (GPS) receiver. In some examples, localization system 406 receives GNSS data associated with the location of the vehicle in the area and localization system 406 determines a latitude and longitude of the vehicle in the area. In such an example, localization system 406 determines the position of the vehicle in the area based on the latitude and longitude of the vehicle. In some embodiments, localization system 406 generates data associated with the position of the vehicle. In some examples, localization system 406 generates data associated with the position of the vehicle based on localization system 406 determining the position of the vehicle. In such an example, the data associated with the position of the vehicle includes data associated with one or more semantic properties corresponding to the position of the vehicle.

In some embodiments, control system 408 receives data associated with at least one trajectory from planning system 404 and control system 408 controls operation of the vehicle. In some examples, control system 408 receives data associated with at least one trajectory from planning system 404 and control system 408 controls operation of the vehicle by generating and transmitting control signals to cause a powertrain control system (e.g., DBW system 202h, powertrain control system 204, and/or the like), a steering control system (e.g., steering control system 206), and/or a brake system (e.g., brake system 208) to operate. In an example, where a trajectory includes a left turn, control system 408 transmits a control signal to cause steering control system 206 to adjust a steering angle of vehicle 200, thereby causing vehicle 200 to turn left. Additionally, or alternatively, control system 408 generates and transmits control signals to cause other devices (e.g., headlights, turn signal, door locks, windshield wipers, and/or the like) of vehicle 200 to change states.

In some embodiments, perception system 402, planning system 404, localization system 406, and/or control system 408 implement at least one machine learning model (e.g., at least one multilayer perceptron (MLP), at least one convolutional neural network (CNN), at least one recurrent neural network (RNN), at least one autoencoder, at least one transformer, and/or the like). In some examples, perception system 402, planning system 404, localization system 406, and/or control system 408 implement at least one machine learning model alone or in combination with one or more of the above-noted systems. In some examples, perception system 402, planning system 404, localization system 406, and/or control system 408 implement at least one machine learning model as part of a pipeline (e.g., a pipeline for identifying one or more objects located in an environment and/or the like).

Database 410 stores data that is transmitted to, received from, and/or updated by perception system 402, planning system 404, localization system 406 and/or control system 408. In some examples, database 410 includes a storage component (e.g., a storage component that is the same as or similar to storage component 308 of FIG. 3) that stores data and/or software related to the operation and uses at least one system of autonomous vehicle compute 400. In some embodiments, database 410 stores data associated with 2D and/or 3D maps of at least one area. In some examples, database 410 stores data associated with 2D and/or 3D maps of a portion of a city, multiple portions of multiple cities, multiple cities, a county, a state, a State (e.g., a country), and/or the like). In such an example, a vehicle (e.g., a vehicle that is the same as or similar to vehicles 102 and/or vehicle 200) can drive along one or more drivable regions (e.g., single-lane roads, multi-lane roads, highways, back roads, off road trails, and/or the like) and cause at least one LiDAR sensor (e.g., a LiDAR sensor that is the same as or similar to LiDAR sensors 202b) to generate data associated with an image representing the objects included in a field of view of the at least one LiDAR sensor.

In some embodiments, database 410 can be implemented across a plurality of devices. In some examples, database 410 is included in a vehicle (e.g., a vehicle that is the same as or similar to vehicles 102 and/or vehicle 200), an autonomous vehicle system (e.g., an autonomous vehicle system that is the same as or similar to remote AV system 114, a fleet management system (e.g., a fleet management system that is the same as or similar to fleet management system 116 of FIG. 1, a V2I system (e.g., a V2I system that is the same as or similar to V2I system 118 of FIG. 1) and/or the like.

In embodiments, the devices described with respect to FIG. 1-4 are tested to determine calibration parameters associated with the device, verify proper operation of the device (e.g., the received data values are accurate and precise), or to troubleshoot anomalies associated with the device. For example, IMUs are often tested using motion simulators that replicate real-world motion. In particular, a device under test (DUT) is subjected to movement and forces that test the capture of raw data obtained by the device. In the example of an IMU, the raw data captured by the device is used to calculate one or more of an orientation, velocity, or position relative to a global reference frame. Generally, an IMU located on an AV captures changes in pitch, roll, and yaw associated with the AV. In embodiments, the IMU characterizes motion of the AV with six degrees of freedom (X+/−, Y+/−, Z+/−).

Traditional IMU test fixtures are large and cost-prohibitive. For example, IMUs are traditionally tested using massive, expensive industrial capital equipment. The traditional test fixtures are often mounted to large concrete piers or other large structures with permanent foundations for stability. The present techniques enable a two axis test fixture that is generally portable and cost-effective. A test fixture according to the present techniques is not mounted to a permanent structure and can be moved as needed. The two-axis fixture according to the present techniques enables testing, calibration, and verification of an IMU. In embodiments, the test fixture is small enough to fit within a thermal chamber. In examples, the test fixture is mounted to a surface such as a table or workbench.

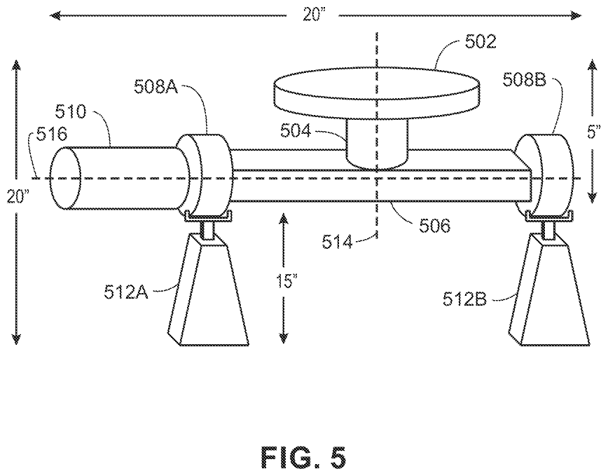

FIG. 5 is a block diagram of a two-axis test fixture 500. In the example of FIG. 5, a turntable 502 is illustrated. During testing, validation, or calibration, a device under test (not illustrated) is mounted atop the turntable 502. The turntable 502 is coupled with a first motor 504. The first motor 504 may include one or more slip rings. A slip ring enables an electrical connection through a rotating assembly. In examples, the slip ring is an electric transmission device that enables energy flow between two electrical rotating parts of the motor. A second motor 510 rotates an axle 506 about a second axis 516 using one or more slip rings. In embodiments, the first motor 504 and the second motor 510 are controlled by a single power line. The single power line transmits data that indicates how long to drive each motor, and when to halt the drive signal associated with each motor. The present techniques approximate three axes of rotation with only two gimbals (e.g., points of rotation) at the test device. The present techniques result in cost savings due to the smaller size of the test fixture.

During operation, the first motor 504 is operable to rotate (e.g., spin) the turntable 502. In particular, the first motor 504 causes a rotation of the turntable about a first axis 514 that is perpendicular to the second axis 516 that extends along the axle 506. In embodiments, the axle 506 is a central shaft that is coupled with two rotational bearings. In the example of FIG. 5, the axle 506 is coupled with a rotational bearing 508A and a rotational bearing 508B (collectively referred to as rotational bearings 508). In embodiments, the rotational bearings 508 constrain the relative motion of the axle 506 to a rotation about the second axis 516 that extends along the length of the axle 506. In embodiments, the rotational beatings 508 reduce friction between moving parts. In embodiments, the rotational bearings 508 rotate 180° while being firmly mounted to a standoff fixture 512A or a standoff fixture 512B.

The second motor 510 drives the rotation of the axle 506 about the second axis 516. In embodiments, the second motor 510 is coupled with one or more slip rings that enable rotation. In this manner, rotation of the axle 506 about the second axis 516 causes a revolution of the turntable 502 about the second axis 516. Accordingly, the turntable 502 is operable to simultaneously rotate about a first axis 514 and revolve about a second axis 516. In this manner, a device under test mounted to the turntable 502 is instructed to progress through six degrees of motion respective to the device under test.

As illustrated in the example of FIG. 5, the turntable 502, first motor 504, axle 506, rotational bearings 508, and second motor 510 are supported by a standoff fixture 512A and standoff fixture 512B (collectively referred to as standoff fixtures 512). In embodiments, the standoff fixtures 512 provide support to the axle 506, while enabling clearance underneath the supported axle 506 and rotation of the supported axle 506. The support fixtures 512 can include one or more cross-members that form a truss to support the axle, beam, or central shaft. In embodiments, the cross-members provide support for the standoff fixture.

Additionally, in the example of FIG. 5, the standoff fixtures 512 enable a clearance below the axle 506 of approximately fifteen inches. A height of the test fixture 500 is approximately twenty inches, and a length of the test fixture 500 is approximately twenty inches. A distance from the bottom of the axle 506 to the top of the turntable 502 is approximately five inches.

The fixture 500 of FIG. 5 is not intended to indicate that the fixture 500 is to include all of the components shown in FIG. 5. Rather, the fixture 500 can include fewer or additional components not illustrated in FIG. 5 (e.g., additional motors, bearings, slip rings, turntables, standoff fixtures, cross-members, etc.). The fixture 500 may include any number of additional components not shown, depending on the details of the specific implementation.

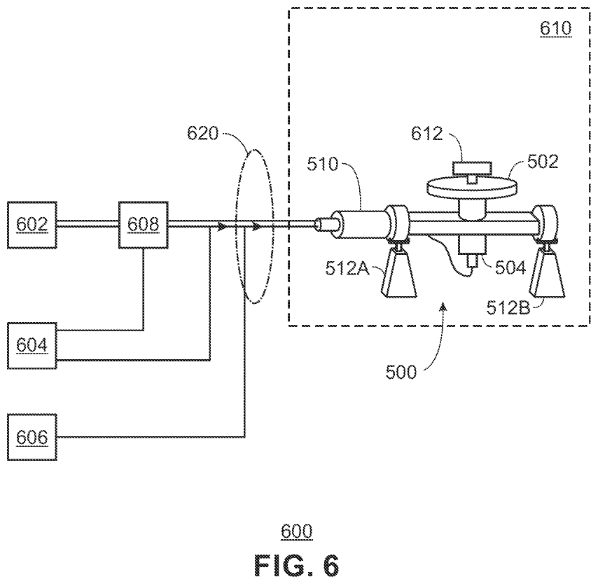

FIG. 6 is an illustration of a test system 600. In the test system 600, a single board computer (SBC) 602, power supply 604, and controller 606 are illustrated. In embodiments, a motor drive amplifier 608 receives commands (e.g., control signals) from the SBC 602 and power from the power supply 604. The motor drive amplifier 608 generates drive signals to operate the device under test 612 and the test fixture 500. In examples, the SBC 602 outputs one or more control signals as defined by a predetermined script or code. These signals are received by the motor drive amplifier 608. The power supply 604 drives the motor. The control signals are sent to the motor drive amplifier 608, which transmits control signals that cause the motor to rotate. In embodiments, the rotation occurs until a control signal is sent to stop rotation. In embodiments, the duration of time spent driving one or more motors determines the amount of rotation at the device under test. A rate of rotation depends, at least in part, on a maximum output of each motor itself. In embodiments, the controller 606 captures data associated with the control signals sent to one or more motors and the output of the device under test.

In embodiments, the power supply 604 powers the test fixture 500, located within a thermal chamber 610. In particular, the power supply 604 supplies power to a motor drive 608, the first motor 504, the second motor 510, and a device under test 612. In embodiments, the power supply 604 is located remotely from the device under test 612 and thermal chamber 610. In embodiments, the entire device under test is located within the thermal chamber, and cables 620 pass through the thermal chamber to drive the test fixture 500. In particular, the cables 620 are routed through one or more slip rings to power the first motor 504, second motor 510, and device under test 612.

As illustrated in the example of FIG. 6, the fixture 500 is located within the thermal chamber 610. The temperature within the thermal chamber is adjusted to subject the device under test to varying thermal conditions. In this manner, the present techniques enable testing of devices across various temperatures. In particular, the present techniques provide a turntable 502 that rotates about two axes within a temperature chamber. In embodiments, the device under test 612 is mounted on the turntable 502 and various wires and cables 620 are connected to the device under test and the turntable to provide power and control signals across a range of predetermined temperatures. The cables 620 enable control signals that originate from a remote location. In examples, the test fixture and thermal chamber are located in a different room or building that is separate from the SCB 602, power supply 604, and controller 606.

The system 600 of FIG. 6 is not intended to indicate that the system 600 is to include all of the components shown in FIG. 6. Rather, the system 600 can include fewer or additional components not illustrated in FIG. 6 (e.g., additional motors, bearings, slip rings, turntables, standoff fixtures, thermal chambers, etc.). The system 600 may include any number of additional components not shown, depending on the details of the specific implementation. Furthermore, the generation of control signals, control of the test fixture, and/or control of the thermal chamber may be partially, or entirely, implemented in hardware and/or in a processor. For example, the functionality may be implemented with an application specific integrated circuit, in logic implemented in a processor, in logic implemented in a specialized graphics processing unit, or in any other device.

In embodiments, the first motor and the second motor are direct current (DC) motors with built-in rotation detection (giving an absolute or relative angle of the drive shaft). For example, each motor includes a rotation detection system that determines a true position of the first motor and a true position of the second motor. This can be used to determine position of the device under test based on the absolute or relative angle of the drive shaft output by the first motor and second motor. Further, in examples, each motor includes an initialization function to reset to zero or a known starting point. For purposes of explanation, assume that three seconds of driving (e.g. transmitting a control signal to rotate the first motor, the second motor, or any combination thereof) in either direction represents a 90 degree rotation. The following is exemplary pseudo-code for motor control:

| | |
|---|---|
| PowerSupply.On | |
| SBC_Initialize(Motor1) | |
| SBC_Initialize(Motor2) | |
| SBC_Drive_Pos(Motor1) | //turn on motor in “positive” direction |
| time.sleep(3) | //drive for +90 degrees |
| SBC_Stop(Motor1) | //stop |
| SBC_Drive_Neg(Motor2) | //turn on motor in “negative” direction |
| time.sleep(3) | //drive for −90 degrees |
| SBC_Stop(Motor2) | //stop |

In embodiments, the pseudo code for motor control is used in conjunction with other test scripts actually capturing test data output by the device under test or directly controlling the thermal chamber.

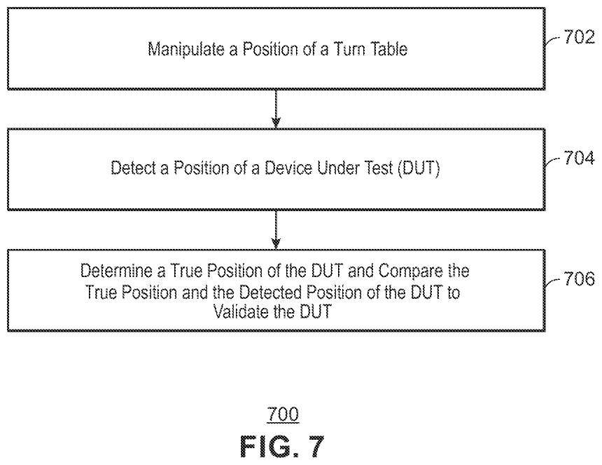

FIG. 7 is a process flow diagram of a process for control of a two-axis test fixture. At block 702, a position of a turntable is manipulated. In embodiments, a device under test (e.g., inertial measurement unit) is mounted on the turntable. A processor (e.g., single board computer 602) generates a signal to control a rotation of the turntable, a rotation of an axle, or any combinations thereof. In embodiments, the control signal is based on a predetermined script or code.

At block 704, a position of the device under test is detected. In embodiments, the detected position is captured by the device under test as the turntable is manipulated. The turntable is coupled with an axle, wherein the turntable rotates about a first axis that is perpendicular to a second axis that extends along the length of the axle. Accordingly, a position of the device under test is detected based on the manipulation of the position of the turntable, wherein the manipulation of the position of turntable comprises rotation of the turntable about a first axis that is perpendicular to a second axis and rotation of the axle about the second axis. The rotation of the axle about the second axis ultimately causes the turntable and device under test to revolve about the second axis.

In embodiments, the first motor and the second motor are DC motor drives controlled by an amplifier/motor controller which is located remotely (at the end of a cable harness) relative to the motors. In this manner, the test fixture (including turntables, motors, and the device under test) is isolated within a thermal chamber. During operation, the thermal chamber enables testing across a wide temperature range, for example −40 C up to +85 C. Generally, the more temperature sensitive components of a test system (such as the motor drive amplifier 508, controllers 606, power supply 604, and SBC 606 to control equipment for the DUT) are located at the end of a cable harness 620, outside of the thermal chamber 610 (FIG. 6).

At block 706, a true position of the device under test is determined. For example, the true position of the device under test is determined by a controller that receives the at least one control signal that controls a rotation of the turntable, a rotation of an axle, or any combinations thereof. The true position of the device under test is compared with the detected position of the device under test to validate the device under test.

This process flow diagram is not intended to indicate that the blocks of the example process 700 are to be executed in any particular order, or that all of the blocks are to be included in every case. Further, any number of additional blocks not shown may be included within the example process 700, depending on the details of the specific implementation.

In the foregoing description, aspects and embodiments of the present disclosure have been described with reference to numerous specific details that can vary from implementation to implementation. Accordingly, the description and drawings are to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims. In addition, when we use the term “further comprising,” in the foregoing description or following claims, what follows this phrase can be an additional step or entity, or a sub-step/sub-entity of a previously-recited step or entity.

1. An apparatus, comprising:
a turntable coupled with an axle, wherein the turntable rotates about a first axis that is perpendicular to a second axis, and the axle rotates about the second axis;
a first motor that controls the rotation of the turntable;
a second motor that controls the rotation of the axle; and
a support fixture to enable clearance of the turntable coupled with the axle as it rotates about the second axis.

2. The apparatus of claim 1, wherein the first motor controls the rotation of the turntable via connections through a first slip ring.

3. The apparatus of claim 1, wherein the second motor controls the rotation of the axle via connections through a second slip ring.

4. The apparatus of claim 1, wherein the first motor and the second motor comprise a rotation detection system that determines a true position of the first motor and a true position of the second motor.

5. The apparatus of claim 1, wherein the axle is coupled to the support fixture via at least one rotational bearing.

6. The apparatus of claim 1, further comprising a thermal chamber, wherein the turntable, axle, first motor, second motor, and support fixture are operable within the thermal chamber.

7. A system, comprising:
at least one computer-readable medium storing computer-executable instructions;
at least one processor communicatively coupled to the computer readable medium and configured to execute the computer executable instructions, the execution carrying out operations including:
manipulating a position of a turntable while a device under test is mounted on the turntable, wherein, when manipulating the position of the turntable, the computer-executable instructions cause the at least one processor to transmit a least one control signal configured to cause rotation of the turntable, rotation of an axle, or any combinations thereof;
detecting, using the device under test, a position of the device under test based on the manipulation of the position of the turntable, wherein the manipulation of the position of the turntable comprises rotation of the turntable about a first axis that is perpendicular to a second axis and rotation of the axle about the second axis; and
comparing a true position of the turntable and the detected position of the device under test to validate the device under test.

8. The system of claim 7, wherein execution of the computer executable instructions further cause the operation of:
determining the true position of the turntable based on the manipulation of the position of the turntable.

9. The system of claim 7, wherein the controller controls the rotation of the turntable via connections to a first motor through a first slip ring.

10. The system of claim 7, wherein the controller controls the rotation of the axle via connections to a second motor through a second slip ring.

11. The system of claim 7, wherein the controller controls the movement of the device under test through six degrees of freedom.

12. The system of claim 7, wherein the position of the turntable is controlled by a predetermined script.

13. The system of claim 7, wherein the device under test is tested in a temperature controlled vacuum.

14. A method, comprising:
manipulating, using at least one processor, a position of a turntable while a device under test is mounted on the turntable by transmitting at least one control signal configured to cause rotation of the turntable, rotation of an axle, or any combinations thereof;
detecting, using the device under test, a position of the device under test based on the manipulation of the position of the turntable, wherein the manipulation of the position of turntable comprises rotation of the turntable about a first axis that is perpendicular to a second axis and rotation of the axle about the second axis; and
determining, using the at least one processor, a true position of the device under test based on the at least one control signal, wherein the true position of the device under test is compared with the detected position of the device under test to validate the device under test.

15. The method of claim 14, wherein the controller controls the rotation of the turntable via connections to a first motor through a first slip ring.

16. The method of claim 14, wherein the controller controls the rotation of the axle via connections to a second motor through a second slip ring.

17. The method of claim 14, wherein the controller controls the movement of the device under test through six degrees of freedom.

18. The method of claim 14, wherein the position of the turntable is controlled by a predetermined script.

19. The method of claim 14, wherein the device under test is tested in a temperature controlled vacuum.
